(19) United States
(12) Patent Application Publication
(10) Pub. No.: US 2026/0013399 A1
(43) Pub. Date: Jan. 8, 2026

(54) METHODS FOR FABRICATING THE MEMORY CELL AND THE SEMICONDUCTOR MEMORY DEVICE

(71) Applicant: SK hynix Inc., Icheon-si (KR)

(72) Inventors: Jeong Myeong KIM, Icheon-si (KR); Cha Deok DONG, Icheon-si (KR); Keo Rock CHOI, Icheon-si (KR)

(21) Appl. No.: 19/194,638

(22) Filed: Apr. 30, 2025

(30) Foreign Application Priority Data
Jul. 2, 2024 (KR) 10-2024-0086823

(51) Int. Cl. H10N 50/01; G11C 5/06; H10B 61/00; H10N 50/10; H10N 50/85

(52) U.S. Cl. CPC H10N 50/01; G11C 5/063; H10B 61/20; H10N 50/10; H10N 50/85

(57) ABSTRACT

Memory cell structures, semiconductor memory devices, and their fabrication methods are disclosed. In an embodiment, method for fabricating a semiconductor device includes: forming a lower interconnect over a base layer; forming a memory cell structure over the lower interconnect; and forming an upper interconnect over the memory cell structure, wherein the forming of the memory cell structure includes: forming an initial selection element material layer; performing a first doping process that provides first dopants into the initial selection element material layer to reform the initial selection element material layer into a first doped selection element material layer; performing a second doping process that provides second dopants into the first doped selection element material layer to reform the first doped selection element material layer into a second doped selection element material layer; and forming a selection element layer by patterning the second doped selection element material layer.

### CROSS-REFERENCE TO RELATED APPLICATIONS

The patent document claims the priority and benefits of Korean Patent Application No. 10-2024-0086823, filed on Jul. 2, 2024, in the Korean Intellectual Property Office, which is incorporated herein by reference in its entirety.

### TECHNICAL FIELD

The technology disclosed in this patent document generally relates to a semiconductor device including memory cells, and methods for fabricating the semiconductor device.

### BACKGROUND

With the miniaturization, low power consumption, high performance, and diversification of electronic devices, there is a growing demand for semiconductor devices capable of storing data in various electronic devices, such as computers and portable communication devices, and research in this field is actively underway. Such semiconductor devices utilize the property of switching between different resistance states depending on the applied voltage or current to store data. Examples may include a Resistive Random Access Memory (RRAM), a Phase-change Random Access Memory (PRAM), a Ferroelectric Random Access Memory (FRAM), a Magnetic Random Access Memory (MRAM), and an e-fuse.

### SUMMARY

The disclosed technology can be implemented in some embodiments to provide semiconductor devices and memory cells with a specific structure.

The disclosed technology can also be implemented in some embodiments to provide a method for fabricating a semiconductor device, and a method for fabricating a memory cell with a specific structure.

In an embodiment of the disclosed technology, a semiconductor device includes: a lower interconnect extending in a first horizontal direction; an upper interconnect extending in a second horizontal direction perpendicular to the first horizontal direction; and a memory cell structure arranged in a pillar shape between the lower interconnect and the upper interconnect, wherein the memory cell structure includes: a selection element layer; a memory element layer; and an intermediate electrode disposed between the selection element layer and the memory element layer, and the selection element layer includes: at least one of silicon oxide, silicon nitride, or silicon oxynitride; a first dopant including at least one of boron, aluminum, gallium, indium, or thallium; and a second dopant including at least one of arsenic, phosphorus, or germanium. In an embodiment, the selection element layer is configured to exhibit different electrical conducting characteristics in response to an applied voltage or current with respect to a threshold voltage or current. In an embodiment, the memory element layer is configured to store data.

In another embodiment of the disclosed technology, a semiconductor device includes: a lower interconnect; an upper interconnect; and a memory cell structure between the lower interconnect and the upper interconnect, wherein the memory cell structure includes: a selection element layer; a memory element layer; and an intermediate electrode between the selection element layer and the memory element layer, and the selection element layer includes boron/arsenic-doped silicon nitride.

In another embodiment of the disclosed technology, a memory cell structure includes: a selection element layer; a memory element layer; and an intermediate electrode between the selection element layer and the memory element layer, wherein the selection element layer includes: at least one of silicon oxide, silicon nitride, or silicon oxynitride; and boron and arsenic that are doped by a plasma doping process, and the memory element layer includes a magnetic tunnel junction (MTJ), and the intermediate electrode includes at least one of a carbon layer, a carbon compound layer, a plurality of graphene layers, a graphite layer, or a carbon nanotube.

In another embodiment of the disclosed technology, a method for fabricating a semiconductor device includes: forming a lower interconnect over a base layer; forming a memory cell structure over the lower interconnect; and forming an upper interconnect over the memory cell structure, wherein the forming of the memory cell structure includes: forming an initial selection element material layer; performing a first doping process that provides first dopants into the initial selection element material layer to reform the initial selection element material layer into a first doped selection element material layer; performing a second doping process that provides second dopants into the first doped selection element material layer to reform the first doped selection element material layer into a second doped selection element material layer; and forming a selection element layer by patterning the second doped selection element material layer.

In another embodiment of the disclosed technology, a method for fabricating a semiconductor device includes:
forming a lower interconnect; forming a memory cell structure over the lower interconnect; and forming an upper interconnect over the memory cell structure, wherein the forming of the memory cell structure includes: forming an initial selection element material layer; reforming the initial selection element material layer into a doped selection element material layer by performing a doping process so as to dope first dopants and second dopants into the initial selection element material layer; and forming a selection element layer by patterning the doped selection element material layer.

### BRIEF DESCRIPTION OF THE DRAWINGS

FIG. 1 is a perspective view schematically illustrating a cross-point type cell array of a semiconductor device based on an embodiment of the disclosed technology.

FIGS. 2A to 2D illustrate methods for forming a selection element layer of a memory cell structure of a semiconductor device based on embodiments of the disclosed technology.

FIGS. 3A to 3D schematically illustrate unit cell structures of a cell array of a semiconductor device based on embodiments of the disclosed technology.

FIGS. 4A to 4F, FIGS. 5A to 5D, FIGS. 6A to 6D, and FIGS. 7A to 7D illustrate methods for fabricating a semiconductor device and methods for forming a memory cell structure based on embodiments of the disclosed technology.

### DETAILED DESCRIPTION

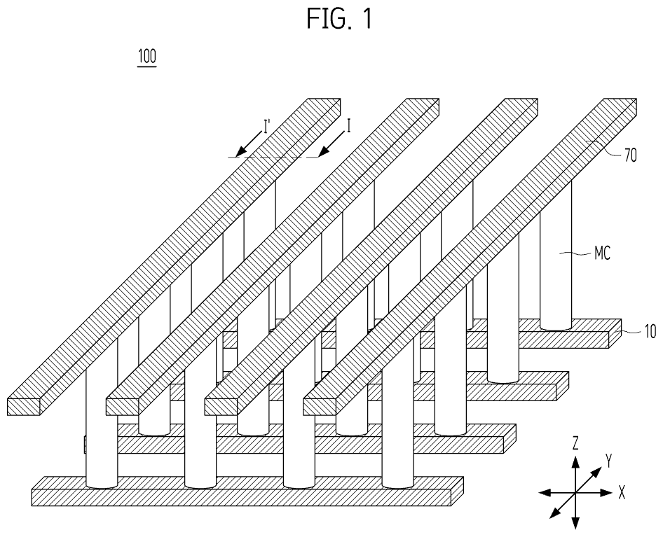

FIG. 1 is a perspective view schematically illustrating a cross-point type cell array 100 of a semiconductor device based on an embodiment of the disclosed technology. Referring to FIG. 1, the cross-point type cell array 100 of a memory device based on the embodiment of the disclosed technology may include a plurality of lower interconnects 10, a plurality of upper interconnects 70, and a plurality of memory cell structures MC. The lower interconnects 10 may extend parallel to each other in a first horizontal direction X. The upper interconnects 70 may extend parallel to each other in a second horizontal direction Y. The memory cell structures MC may be disposed at the intersections between the lower interconnects 10 and the upper interconnects 70, respectively. Each of the memory cell structures MC may have a cylindrical pillar shape extending in a vertical direction Z. The first horizontal direction X, the second horizontal direction Y, and the vertical direction Z may be perpendicular to each other.

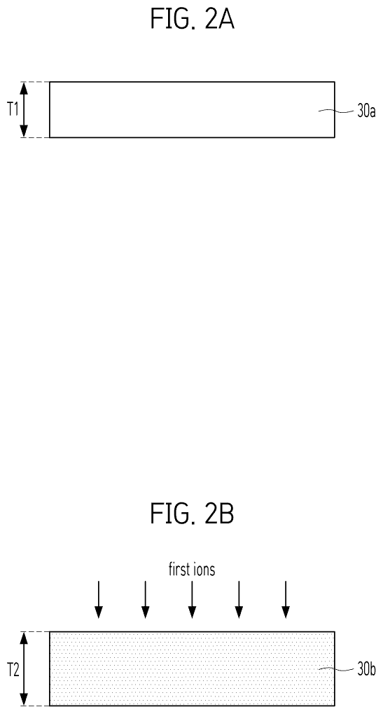

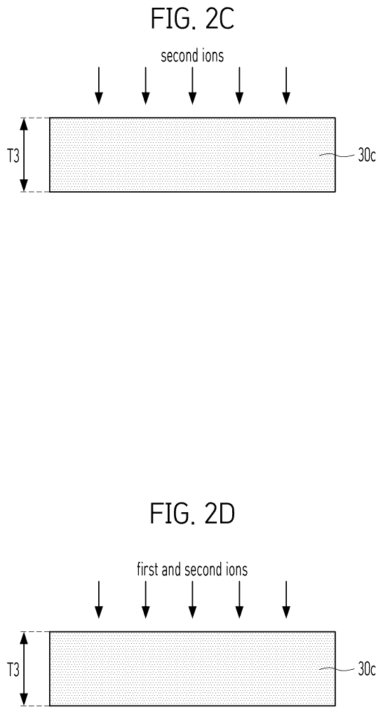

FIGS. 2A to 2D illustrate methods for forming a selection element layer of a memory cell structure of a semiconductor device based on embodiments of the disclosed technology.

Referring to FIG. 2A, a method for forming a selection element layer of a memory cell structure of a semiconductor device based on an embodiment of the disclosed technology may include forming an initial selection element material layer 30a by performing a deposition process, such as a chemical vapor deposition (CVD) process. The initial selection element material layer 30a may include at least one of a silicon oxide (SiO₂) layer, a silicon nitride (SiN) layer, or a silicon oxynitride (SiON) layer. The initial selection element material layer 30a may be formed to have a first thickness T1.

Referring to FIG. 2B, the method may include performing a first doping process to implant first dopants into the initial selection element material layer 30a. The first doping process may include a plasma doping process. For example, the first doping process may include performing a plasma doping process and diffusing the first dopants into the initial selection element material layer 30a by using a first gas including the first dopants. In this way, the initial selection element material layer 30b may be reformed into a first doped selection element material layer 30b. In one embodiment of the disclosed technology, the first dopants may include boron (B). For example, the first gas may include at least one of boron fluoride (BF₃), boron chloride (BCl₃), boron bromide (BBr₃), or boron hydride (B₂H₆). In one embodiment of the disclosed technology, the first gas may include at least one of nitrogen (N), oxygen (O), carbon (C), fluorine (F), chlorine (Cl), or boron (B).

The first doped selection element material layer 30b may be reformed into a boron-doped silicon nitride layer, a boron-doped silicon oxide layer, or a boron-doped silicon oxynitride layer. In one embodiment of the disclosed technology, the first dopants may include at least one of aluminum (Al), gallium (Ga), indium (In), or thallium (Tl) instead of boron (B).

In one embodiment of the disclosed technology, the plasma diffused boron (B) ions may form silicon-boron (Si—B) bonds, boron-oxygen (B—O) bonds, boron-nitrogen (B—N) bonds, silicon-boron-nitrogen (Si—B—N) bonds, silicon-boron-oxygen (Si—B—O) bonds, or silicon-boron-oxygen-nitrogen (Si—B—O—N) bonds in the initial selection element material layer 30a. Since the boron (B) atoms are smaller than silicon (Si) atoms, oxygen (O) atoms, and nitrogen (N) atoms, the boron (B) atoms may be uniformly distributed in the initial selection element material layer 30a through a plasma diffusion process. When the boron (B) atoms are implanted into the initial selection element material layer 30a by performing an ion implantation process, the initial selection element material layer 30a may be physically damaged. Also, the boron (B) atoms may penetrate the initial selection element material layer 30a to be disposed close to a lower electrode material layer 20a. Since boron (B) atoms are small in size, they may easily penetrate the initial selection element material layer 30a. In other words, when boron (B) atoms are implanted into the initial selection element material layer 30a by performing an ion implantation process, the boron (B) atoms may penetrate the initial selection element material layer 30a and form a chemical bond with the lower electrode material layer 20a. In other words, the electrical resistance of the lower electrode material layer 20a and/or the lower interconnect 10 may increase. When the boron (B) atoms are implanted into the initial selection element material layer 30a through a plasma doping process and a diffusion process based on an embodiment of the disclosed technology, the boron (B) atoms may be uniformly diffused and distributed in the initial selection element material layer 30a.

The first dopants doped in the initial selection element material layer 30a may form a chemical bond with carbon (C) atoms. Therefore, the gap between the carbon (C) atoms of the initial selection element material layer 30a may increase, and the volume of the initial selection element material layer 30a may expand. For example, the first doped selection element material layer 30b may have a second thickness T2. The second thickness T2 may be greater than the first thickness T1.

Referring to FIG. 2C, the method may include performing a second doping process to implant second dopants into the first doped selection element material layer 30b. In this way, the first doped selection element material layer 30b may be reformed into a second doped selection element material layer 30c. The second dopants may include at least one of arsenic (As), phosphorus (P), or germanium (Ge). In one embodiment of the disclosed technology, the second doping process may include an ion implantation process. For example, the second doping process may include performing an ion implantation process to implant the second dopants into the first doped selection element material layer 30b. The second dopants may include at least one of arsenic (As), phosphorus (P), or germanium (Ge).

In one embodiment of the disclosed technology, the second doping process may include a plasma doping process using a second gas. For example, the second doping process may include performing a plasma doping process and diffusing the second dopants into the first doped selection element material layer 30b by using a second gas including the second dopants. The second gas may include at least one of: gases containing arsenic (As), such as AsH₃, AsCl₃, AsCl₅, AsF₃, or AsF₅; gases containing phosphorus (P), such as PH₃, PCl₃, PCI₅, POCl₃, PF₃, or PF₅; or gases containing germanium (Ge), such as GeH₃, GeCl₃, or GeCl₄. For example, the second gas may include: at least one of nitrogen (N), oxygen (O), carbon (C), fluorine (F), or chlorine (CI); and at least one of arsenic (As), phosphorus (P), or germanium (Ge).

In one embodiment of the disclosed technology, the method may include uniformly diffusing and distributing the first dopants and the second dopants in the second doped selection element material layer 30c. For example, the method may further include performing an annealing process.

The second doped selection element material layer 30c may have a third thickness T3. In one embodiment of the disclosed technology, the third thickness T3 may be the same as the second thickness T2. In other words, even if the second dopants are doped into the first doped selection element material layer 30b, the volume of the first doped selection element material layer 30b may not expand. The second dopants may not be bonded with the enlarged carbon (C) atoms but may be disposed in the enlarged gaps between the carbon (C) atoms. In other words, the second dopants may diffuse through the enlarged atomic gaps. Accordingly, the second dopants may have an overall uniform concentration profile in the second doped selection element material layer 30c. In another embodiment of the disclosed technology, the third thickness T3 may be smaller than the second thickness T2. This may be due to damage and loss of part of the first doped selection element material layer 30b during the second doping process.

FIG. 2D illustrates a method for forming a selection element layer of a memory cell structure of a semiconductor device based on an embodiment of the disclosed technology. Referring to FIGS. 2A and 2D, the method may include forming an initial selection element material layer 30a, and then performing a doping process to implant dopants into the initial selection element material layer 30a. The doping process may include a plasma doping process using a doping gas. The doping gas may include carriers and dopants. The carriers may include at least one of nitrogen (N), oxygen (O), carbon (C), fluorine (F), or chlorine (CI). The dopants may include a first dopant and a second dopant. The first dopant may include at least one of boron (B), aluminum (Al), gallium (Ga), indium (In), or thallium (Tl). The second dopant may include at least one of arsenic (As), phosphorus (P), or germanium (Ge). For example, the first dopant and the second dopant may be simultaneously implanted, diffused, and distributed in the initial selection element material layer 30a. In this way, the initial selection element material layer 30a may be reformed into the second doped selection element material layer 30c.

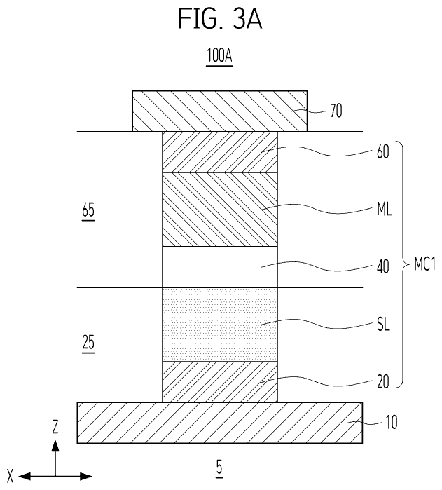

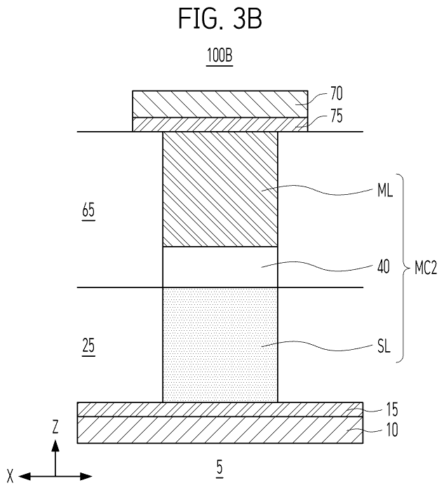

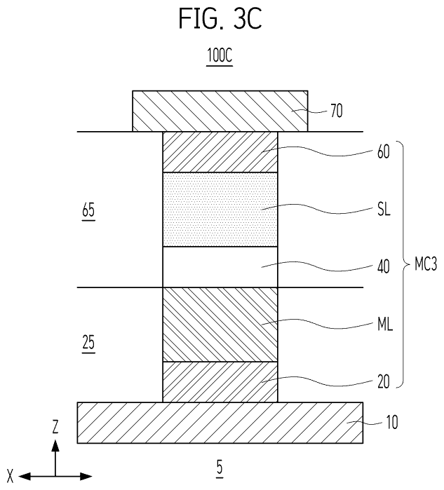

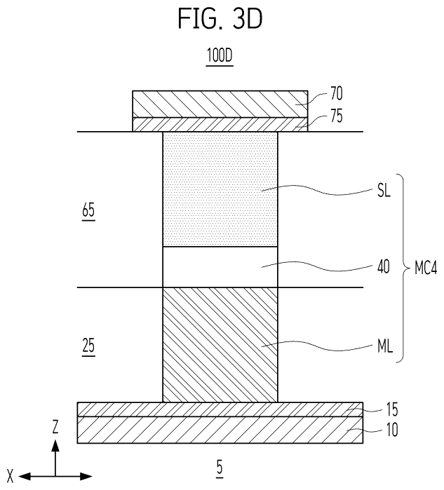

FIGS. 3A to 3D schematically illustrate unit cell structures 100A to 100D of a cell array of a semiconductor device based on embodiments of the disclosed technology. To be specific, they are cross-sectional views taken along a line I-I′ shown in FIG. 1. Referring to FIGS. 3A to 3D, the unit cell structures 100A to 100D of semiconductor devices based on the embodiments of the disclosed technology may include lower interconnects 10, memory cell structures MC1 to MC4, and upper interconnects 70 that are disposed over a base layer 5, respectively. The memory cell structures MC1 to MC4 may be disposed between the lower interconnects 10 and the upper interconnects 70, respectively. Each of the unit cell structures 100A to 100D may further include a lower inter-layer dielectric layer 25 and an upper inter-layer dielectric layer 65 that surround the side surface of each of the memory cell structures MC1 to MC4. The lower inter-layer dielectric layer 25 and the upper inter-layer dielectric layer 65 may include a single-layer of an inorganic dielectric layer or multiple layers of inorganic dielectric layers including a silicon oxide layer or/and a silicon nitride layer. In one embodiment of the disclosed technology, the lower inter-layer dielectric layer 25 and the upper inter-layer dielectric layer 65 may include the same material.

The base layer 5 may include a semiconductor layer or a dielectric layer. For example, the base layer 5 may include a semiconductor layer, such as a silicon wafer, an epitaxially grown layer, or a compound semiconductor. In another embodiment of the disclosed technology, the base layer 5 may include a glass or a glass fiber layer, a ceramic layer, or an inorganic dielectric layer. The inorganic dielectric layer may include a silicon-based dielectric layer, such as silicon oxide or silicon nitride.

The lower interconnect 10 may include a conductor, such as a metal, a metal compound, a metal silicide, or a doped silicon layer. In one embodiment of the disclosed technology, the lower interconnect 10 may include at least one of a metal layer, a metal compound layer, a metal silicide layer, or a metal alloy layer. In one embodiment of the disclosed technology, the lower interconnect 10 may include at least one of a tungsten (W) layer, a titanium (Ti) layer, a tantalum (Ta) layer, a platinum (Pt) layer, an aluminum (Al) layer, a copper (Cu) layer, a zinc (Zn) layer, a nickel (Ni) layer, a cobalt (Co) layer, or a chromium (Cr) layer. In one embodiment of the disclosed technology, the lower interconnect 10 may include at least one of a tungsten nitride (WN) layer, a titanium nitride (TiN) layer, a tantalum nitride (TaN) layer, a titanium silicon nitride (TiSiN) layer, a titanium aluminum nitride (TiAlN) layer, a tantalum silicon nitride (TaSiN) layer, and a titanium aluminum nitride (TiAlN). In one embodiment of the disclosed technology, the lower interconnect 10 may include at least one of tungsten silicide (WSi), titanium silicide (TiSi), nickel silicide (NiSi), or cobalt silicide (CoSi). In one embodiment of the disclosed technology, the lower interconnect 10 may include titanium aluminum (TiAl). The lower interconnect 10 may be either a word line or a bit line. In one embodiment of the disclosed technology, the lower interconnect 10 may be a word line. The lower interconnect 10 may have a line shape extending in the first horizontal direction X.

Each of the memory cell structures MC1 to MC4 may include a selection element layer SL, an intermediate electrode 40, and a memory element layer ML that are disposed between the lower interconnect 10 and the upper interconnect 70.

The selection element layer SL may include a silicon oxide layer or a silicon nitride (SIN) layer that includes first dopants and second dopants. The first dopants may include at least one of boron (B), aluminum (Al), gallium (Ga), indium (In), or thallium (Tl). The second dopants may include at least one of arsenic (As), phosphorus (P), or germanium (Ge).

In one embodiment of the disclosed technology, the first dopants may include boron (B), and the second dopants may include arsenic (As). For example, the selection element layer SL may include at least one of a boron/arsenic-doped silicon oxide layer (B/As-doped SiO2 layer), a boron/arsenic-doped silicon nitride layer (B/As-doped SiN layer), or a boron/arsenic-doped silicon oxynitride layer (B/As-doped SiON layer). The first dopants may be doped through a plasma doping process. The second dopants may be doped through an ion implantation process or a plasma doping process.

In one embodiment of the disclosed technology, the boron (B) dopants may buffer (e.g., fender and absorb) the diffusion and migration of the arsenic (As) dopants implanted in the selection element layer SL. Therefore, the boron (B) dopants may uniformize and stabilize the distribution and density of the arsenic (As) dopants in the selection element layer SL. The boron (B) dopants may trap the carriers to suppress excessive current. In other words, the boron (B) dopants in the selection element layer SL may improve the off-current property and leakage current property of the selection element layer SL.

In one embodiment of the disclosed technology, the selection element material layer SL may include silicon nitride (SIN). The silicon-nitride (Si—N) bonds of silicon nitride (SIN) may be physically stronger than the silicon-oxygen (Si—O) bonds of silicon oxide (SiO₂). Therefore, during an ion implantation process, silicon nitride (SiN) may undergo less physical damage than silicon oxide (SiO₂). Damaged bonds may cause current leakage. Therefore, a silicon nitride (SIN)-based selection element layer SL may have a lower current leakage than a silicon oxide (SiO₂)-based selection element material. As the distribution of arsenic (As), which provides conductive carriers, becomes uniform and stabilized, a conductive channel may be formed more stably in the selection element layer SL. Therefore, the physical thickness of the selection element layer SL may be increased. Consequently, the thicker selection element layer SL may exhibit lower current leakage.

The intermediate electrode 40 may include a conductive material layer. The intermediate electrode 40 may include an amorphous material layer. For example, the intermediate electrode 40 may include a carbon layer. For example, the intermediate electrode 40 may include at least one of a carbon compound layer, a plurality of graphene layers, a graphite layer, or a carbon nanotube.

The memory element layer ML may include a variable resistance layer. For example, the memory element layer ML may include one of a resistive memory layer, a phase changeable memory layer, a magnetic tunnel junction (MTJ), and other variable resistance material layers. In one embodiment of the disclosed technology, the memory element layer ML may include an MTJ. Accordingly, the memory element layer ML may include a lower magnetic layer, a tunneling layer, and an upper magnetic layer. One of the lower magnetic layer and the upper magnetic layer is a free magnetic layer, while the other is a fixed magnetic layer.

Referring to FIGS. 3A and 3B, the memory cell structures MC1 and MC2 of the unit cell structures 100A and 100B may include a selection element layer SL, an intermediate electrode 40 disposed over the selection element layer SL, and a memory element layer ML disposed over the intermediate electrode 40. Referring to FIGS. 3C and 3D, the memory cell structures MC3 and MC4 may include a memory element layer ML, an intermediate electrode 40 disposed over the memory element layer ML, and a selection element layer SL disposed over the intermediate electrode 40.

Referring to FIG. 3A, the memory cell structure MC1 of the unit cell structure 100A may further include a lower electrode 20 disposed below the selection element layer SL and an upper electrode 60 disposed over the memory element layer ML. In other words, the lower electrode 20 may be disposed between the lower interconnect 10 and the selection element layer SL. The upper electrode 60 may be disposed between the memory element layer ML and the upper interconnect 70. The lower electrode 20 and the upper electrode 60 may include a metal compound layer. For example, each of the lower electrode 20 and the upper electrode 60 may include at least one of a tungsten nitride (WN) layer, a titanium nitride (TiN) layer, a tantalum nitride (TaN) layer, a titanium silicon nitride (TiSiN) layer, a titanium aluminum nitride (TiAlN) layer, a tantalum silicon nitride (TaSiN) layer, or a titanium aluminum nitride (TiAlN). In one embodiment of the disclosed technology, the lower electrode 20 and the upper electrode 60 may include a titanium nitride (TIN) layer.

Referring to FIG. 3B, the unit cell structure 100B may further include a lower interconnect barrier layer 15 over the lower interconnect 10 and an upper interconnect barrier layer 75 below the upper interconnect 70. The lower interconnect barrier layer 15 may be disposed between the lower interconnect 10 and the selection element layer SL. The upper interconnect barrier layer 75 may be disposed between the memory element layer ML and the upper interconnect 70. The lower interconnect barrier layer 15 may be conformally disposed over the lower interconnect 10 to extend in the first horizontal direction X. The upper interconnect barrier layer 75 may be conformally disposed below the upper interconnect 70 to extend in the second horizontal direction Y. The lower interconnect barrier layer 15 and the upper interconnect barrier layer 75 may include a metal compound layer. For example, each of the lower interconnect barrier layer 15 and the upper interconnect barrier layer 75 may include at least one of a tungsten nitride (WN) layer, a titanium nitride (TiN) layer, a tantalum nitride (TaN) layer, a titanium silicon nitride (TiSiN) layer, a titanium aluminum nitride (TiAlN) layer, a tantalum silicon nitride (TaSiN) layer, or a titanium aluminum nitride (TiAlN). In one embodiment of the disclosed technology, each of the lower interconnect barrier layer 15 and the upper interconnect barrier layer 75 may include a titanium nitride (TiN) layer.

Referring to FIG. 3C, the memory cell structure MC3 of the unit cell structure 100C may further include a lower electrode 20 disposed below the memory element layer ML and an upper electrode 60 disposed over the selection element layer SL. In other words, the lower electrode 20 may be disposed between the lower interconnect 10 and the memory element layer ML. The upper electrode 60 may be disposed between the selection element layer SL and the upper interconnect 70.

Referring to FIG. 3D, the unit cell structure 100D may further include a lower interconnect barrier layer 15 over the lower interconnect 10 and an upper interconnect barrier layer 75 below the upper interconnect 70. The lower interconnect barrier layer 15 may be disposed between the lower interconnect 10 and the memory element layer ML. The upper interconnect barrier layer 75 may be disposed between the selection element layer SL and the upper interconnect.

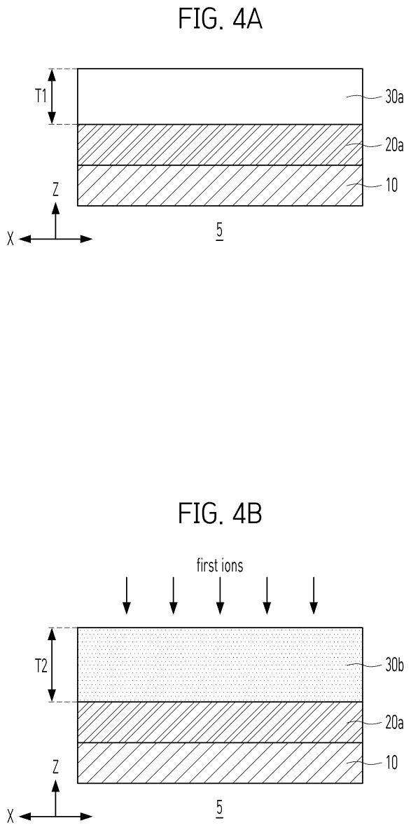

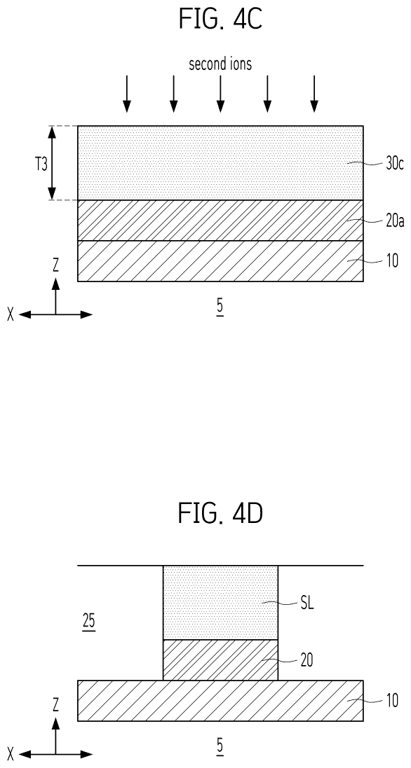

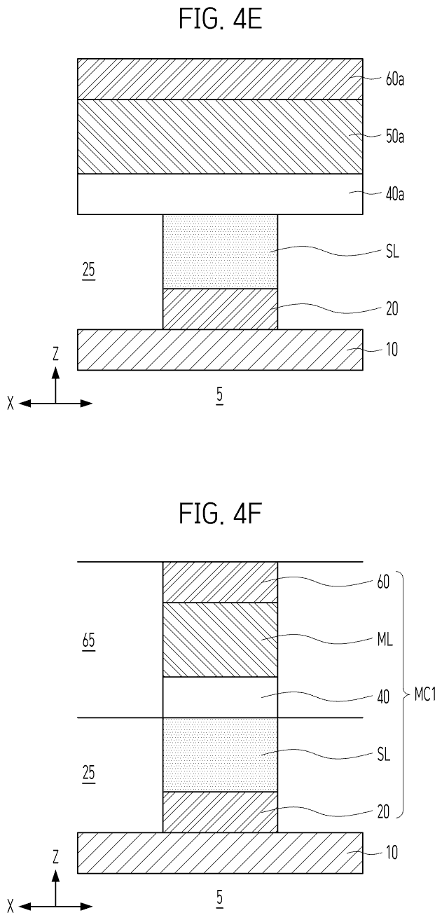

FIGS. 4A to 4F illustrate a method for forming a cell array of a semiconductor device based on an embodiment of the disclosed technology. To be specific, they are cross-sectional views taken along the line I-I′ shown in FIG. 1.

Referring to FIG. 4A, the method for forming a memory cell array of a semiconductor device based on the embodiment of the disclosed technology may include forming a lower interconnect 10, a lower electrode material layer 20a, and an initial selection element material layer 30a over a base layer 5. The base layer 5 may be a silicon wafer or a dielectric layer formed over a silicon wafer. Forming the lower interconnect 10 may include forming a conductive line extending in the first horizontal direction X over the base layer 5 by performing a deposition process and a patterning process.

Forming the lower electrode material layer 20a may include performing a deposition process to form a conductive material layer over the lower interconnect 10. The lower electrode material layer 20a may include at least one of a metal layer, a metal compound layer, a metal silicide layer, or a metal alloy layer. For example, the lower electrode material layer 20a may include at least one of a tungsten (W) layer, a titanium (Ti) layer, a tantalum (Ta) layer, a platinum (Pt) layer, an aluminum (Al) layer, a copper (Cu) layer, a zinc (Zn) layer, a nickel (Ni) layer, a cobalt (Co) layer, or a chromium (Cr) layer. For example, the lower electrode material layer 20a may include at least one of a tungsten nitride (WN) layer, a titanium nitride (TiN) layer, a tantalum nitride (TaN) layer, a titanium silicon nitride (TiSiN) layer, a titanium aluminum nitride (TiAlN) layer, a tantalum silicon nitride (TaSiN) layer, or titanium aluminum nitride (TiAlN). For example, the lower electrode material layer 20a may include at least one of tungsten silicide (WSi), titanium silicide (TiSi), nickel silicide (NiSi), or cobalt silicide (CoSi). For example, the lower electrode material layer 20a may include titanium aluminum (TiAl).

Forming the initial selection element material layer 30a may include performing a deposition process to form a silicon oxide (SiO₂) layer, a silicon nitride (SiN) layer, or a silicon oxynitride (SiON) layer over the lower electrode material layer 20a. The initial selection element material layer 30a may further include at least one of hydrogen (H) or carbon (C). The initial selection element material layer 30a may have a first thickness T1.

Referring to FIG. 4B, the method may further include forming a first doped selection element material layer 30b by performing a first doping process to implant and diffuse the first dopants into the initial selection element material layer 30a.

The first doping process may include a plasma doping process. For example, the first doping process may include implanting and diffusing boron (B) into the initial selection element material layer 30a by using at least one of boron fluoride (BF₃) gas, boron chloride (BCl₃) gas, boron bromide (BBr₃) gas, or boron hydride (B₂H₆) gas with an energy of approximately 1 to 5 KV and a dose of approximately 2.5E15/cm² to 2.5E16/cm².

The volume of the initial selection element material layer 30a may expand as the dopant is doped and diffused into the initial selection element material layer 30a to be chemically bonded with carbon (C) atoms. For example, the first doped selection element material layer 30b may have a second thickness T2. The second thickness T2 may be greater than the first thickness T1.

Referring to FIG. 4C, the method may further include performing a second doping process to implant the second dopants into the first doped selection element material layer 30b.

The method may further include performing an annealing process. As a result of the annealing process, the distribution and density of the first dopants and the second dopants in a second doped selection element material layer 30c may become uniform and stabilized.

In one embodiment of the disclosed technology, the first doping process and the second doping process described by referring to FIG. 4B may be performed as an in-situ process.

In one embodiment of the disclosed technology, the first doping process and the second doping process described by referring to FIG. 4B may be performed simultaneously. For example, first dopants such as boron (B) and second dopants such as arsenic (As) may be simultaneously implanted into the initial selection element material layer 30a to be reformed into the second doped selection element material layer 30c.

The second doped selection element material layer 30c may have a third thickness T3. In one embodiment of the disclosed technology, the third thickness T3 may be the same as the second thickness T2. Since the second dopants are disposed between the carbon (C) atoms, the volume of the first doped selection element material layer 30b may be maintained. In another embodiment of the disclosed technology, the third thickness T3 may be smaller than the second thickness T2.

Referring to FIG. 4D, the method may further include forming a lower electrode 20, a selection element layer SL, and a lower inter-layer dielectric layer 25 by performing a patterning process, a deposition process, and a planarization process. For example, the second doped selection element material layer 30c and the lower electrode material layer 20a may be formed into the selection element layer SL and the lower electrode 20 by performing a patterning process, and the lower inter-layer dielectric layer 25 surrounding the selection element layer SL and the lower electrode 20 may be formed by performing a deposition process and a planarization process. The lower inter-layer dielectric layer 25 may include a dielectric material, such as silicon oxide or silicon nitride. The selection element layer SL, the lower electrode 20, and the lower inter-layer dielectric layer 25 may be co-planar.

Referring to FIG. 4E, the method may further include performing deposition processes to form an intermediate electrode material layer 40a, a memory element material layer 50a, and an upper electrode material layer 60a. The intermediate electrode material layer 40a may include forming at least one of a carbon layer, a carbon compound layer, a plurality of graphene layers, a graphite layer, or a carbon nanotube. Forming the memory element material layer 50a may include forming a magnetic tunnel junction (MTJ). For example, forming the memory element material layer 50a may include forming a lower magnetic layer, a tunneling layer, and an upper magnetic layer.

Referring to FIG. 4F, the method may further include forming an intermediate electrode 40, a memory element layer ML, the upper electrode 60, and an upper inter-layer dielectric layer 65 by performing a patterning process, a deposition process, and a planarization process. For example, the intermediate electrode material layer 40a, the memory element material layer 50a, and the upper electrode material layer 60a may be formed into the intermediate electrode 40, the memory element layer ML, and the upper electrode 60 by performing a patterning process, and an upper inter-layer dielectric layer 65 surrounding the intermediate electrode 40, the memory element layer ML, and the upper electrode 60 may be formed by performing a deposition process and a planarization process. The upper inter-layer dielectric layer 65 may include a dielectric material, such as silicon oxide or silicon nitride. The lower inter-layer dielectric layer 25 and the upper inter-layer dielectric layer 65 may include the same material. The upper electrode 60 and the upper inter-layer dielectric layer 65 may be co-planar. A memory cell structure MC1 including the lower electrode 20, the selection element layer SL, the intermediate electrode 40, the memory element layer ML, and the upper electrode 60 may be formed.

Subsequently, further referring to FIG. 3A, the method may further include performing a deposition process and a patterning process to form an upper interconnect 70 over the memory cell structure MC1 and the upper inter-layer dielectric layer 65. The upper interconnect 70 may have a shape of a conductive line extending in the second horizontal direction Y.

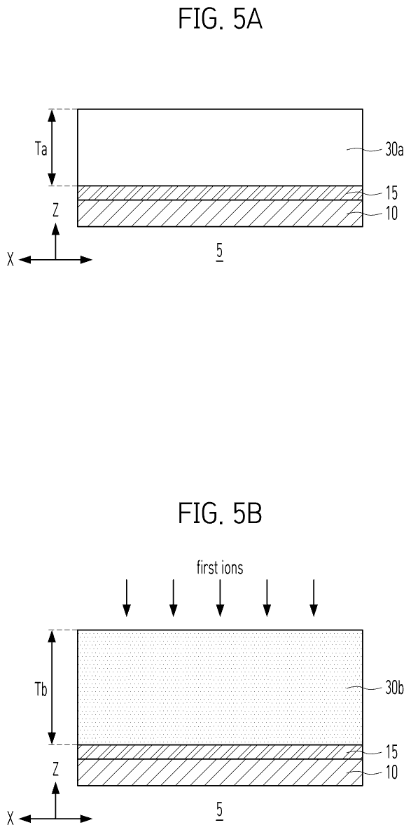

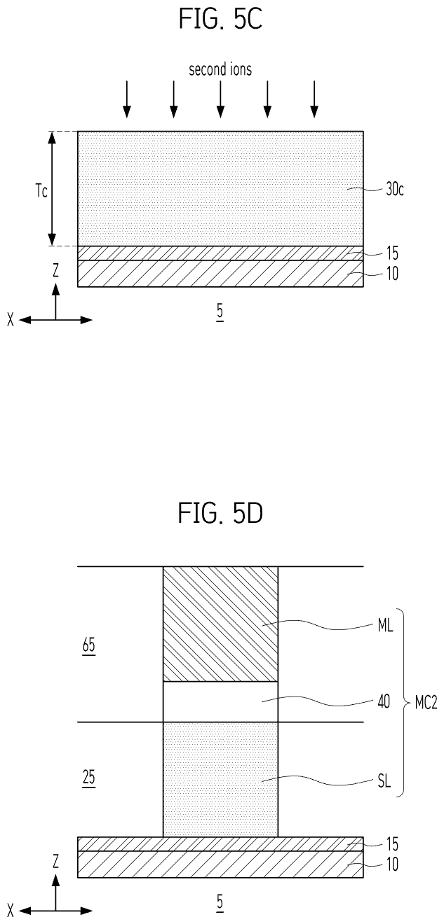

FIGS. 5A to 5D illustrate a method for forming a cell array of a semiconductor device based on an embodiment of the disclosed technology. To be specific, they are cross-sectional views taken along the line I-I′ shown in FIG. 1.

Referring to FIG. 5A, the method for forming a memory cell array of a semiconductor device based on the embodiment of the disclosed technology may include forming a lower interconnect 10, a lower interconnect barrier layer 15, and an initial selection element material layer 30a over a base layer 5. The lower interconnect barrier layer 15 may be conformally formed over the lower interconnect 10. For example, the lower interconnect barrier layer 15 may be formed between the lower interconnect 10 and the initial selection element material layer 30a. The lower interconnect barrier layer 15 may include at least one of titanium nitride (TiN), tantalum nitride (TaN), or tungsten nitride (WN). The lower interconnect barrier layer 15 may have a shape of a conductive line extending in the first horizontal direction X. The initial selection element material layer 30a may be formed to have a first thickness Ta.

Referring to FIG. 5B, the method may further include forming a first doped selection element material layer 30b by performing a first doping process to implant and diffuse first dopants into the initial selection element material layer 30a. The first doped selection element material layer 30b may have a second thickness Tb. The second thickness Tb may be greater than the first thickness Ta.

Referring to FIG. 5C, the method may further include performing a second doping process to implant second dopants into the first doped selection element material layer 30b. In this way, the first doped selection element material layer 30b may be reformed into a second doped selection element material layer 30c. The second doped selection element material layer 30c may have a third thickness Tc. In one embodiment of the disclosed technology, the third thickness Tc may be equal to the second thickness Tb. In another embodiment of the disclosed technology, the third thickness Tc may be smaller than the second thickness Tb.

Referring to FIG. 5D, the method may further include forming a selection element layer SL, a lower inter-layer dielectric layer 25, an intermediate electrode 40, a memory element layer ML, and an upper inter-layer dielectric layer 65 by performing patterning processes, deposition processes, and planarization processes. A memory cell structure MC2 including the selection element layer SL, the intermediate electrode 40, and the memory element layer ML may be formed.

Subsequently, further referring to FIG. 3B, the method may further include forming an upper interconnect barrier layer 75 and an upper interconnect 70 over the memory cell structure MC2 and the upper inter-layer dielectric layer 65 by performing a deposition process and a patterning process. The upper interconnect barrier layer 75 and the upper interconnect 70 may have a shape of a conductive line extending in the second horizontal direction Y.

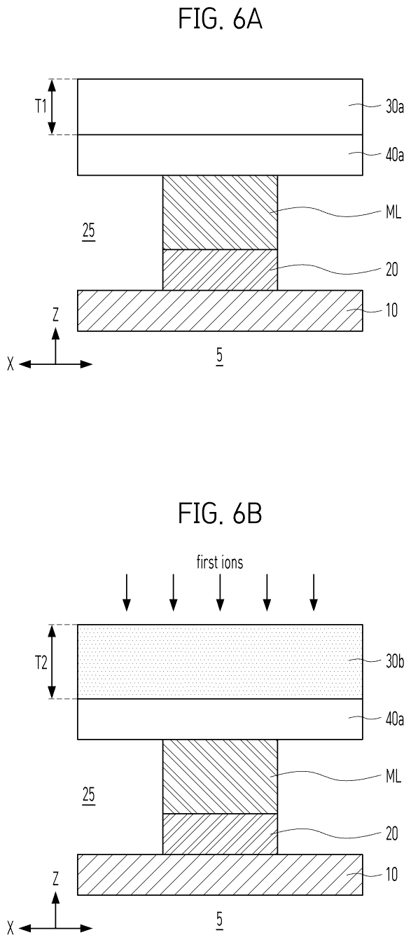

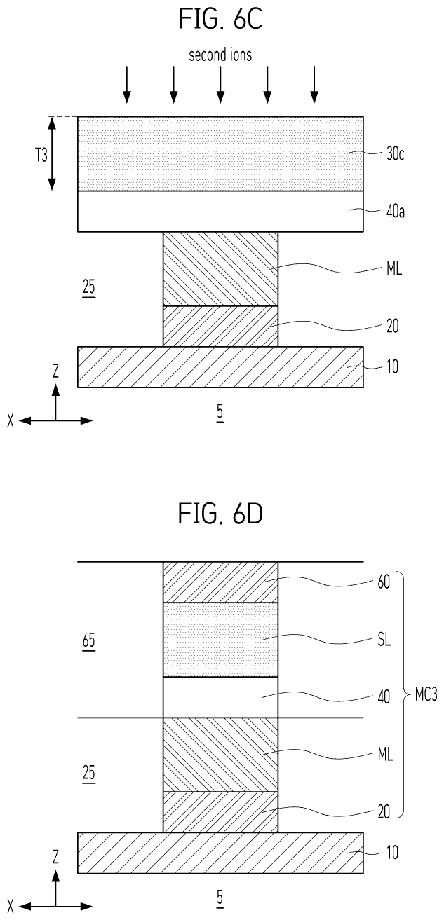

FIGS. 6A to 6D illustrate a method for forming a cell array of a semiconductor device based on an embodiment of the disclosed technology. To be specific, they are cross-sectional views taken along the line I-I′ shown in FIG. 1.

Referring to FIG. 6A, the method of forming a cell array of a semiconductor device based on the embodiment of the disclosed technology may include forming a lower interconnect 10, a lower electrode 20, a memory element layer ML, and a lower inter-layer dielectric layer 25, and forming an intermediate electrode material layer 40a and an initial selection element material layer 30a over the memory element layer ML and the lower inter-layer dielectric layer 25 by performing deposition processes, patterning processes, and planarization processes on the base layer 5. The initial selection element material layer 30a may include a silicon oxide (SiO₂) layer, a silicon nitride (SiN) layer, or a silicon oxynitride (SiON) layer. The initial selection element material layer 30a may further include at least one of hydrogen (H) or carbon (C). The initial selection element material layer 30a may have a first thickness T1.

Referring to FIG. 6B, the method may further include forming a first doped selection element material layer 30b by performing a first doping process to diffuse the first dopants into the initial selection element material layer 30a. The volume of the initial selection element material layer 30a may expand as the dopants are doped and diffused into the initial selection element material layer 30a to be chemically bonded with carbon (C) atoms. For example, the first doped selection element material layer 30b may have a second thickness T2. The second thickness T2 may be greater than the first thickness T1.

Referring to FIG. 6C, the method may further include performing a second doping process to implant the second dopants into the first doped selection element material layer 30b. The second doped selection element material layer 30c may have a third thickness T3. The doped second dopants may be disposed between carbon (C) atoms. In one embodiment of the disclosed technology, the third thickness T3 may be equal to the second thickness T2. In another embodiment of the disclosed technology, the third thickness T3 may be less than the second thickness T2.

Referring to FIG. 6D, the method may further include forming the intermediate electrode 40, the selection element layer SL, the upper electrode 60, and the upper inter-layer dielectric layer 65 by performing patterning processes, deposition processes, and planarization processes. The upper electrode 60 and the upper inter-layer dielectric layer 65 may be co-planar. A memory cell structure MC3 including the lower electrode 20, the memory element layer ML, the intermediate electrode 40, the selection element layer SL, and the upper electrode 60 may be formed.

Subsequently, further referring to FIG. 3C, the method may further include forming an upper interconnect 70 over the memory cell structure MC3 and the upper inter-layer dielectric layer 65 by performing a deposition process and a patterning process. The upper interconnect 70 may have a shape of a conductive line extending in the second horizontal direction Y.

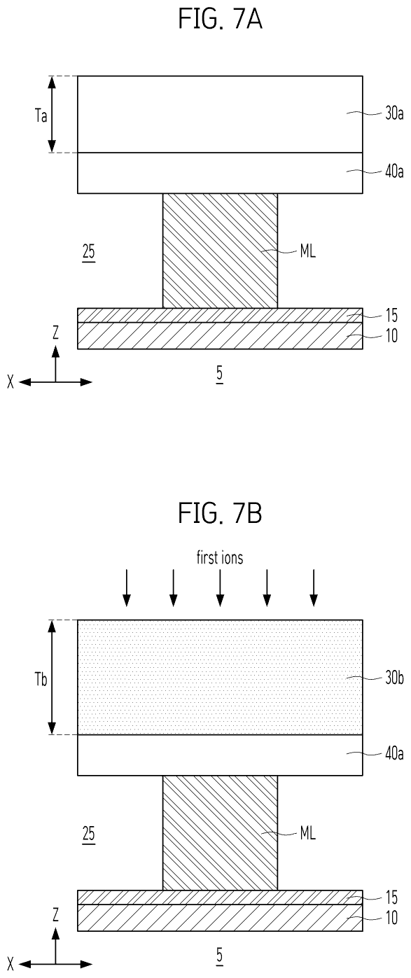

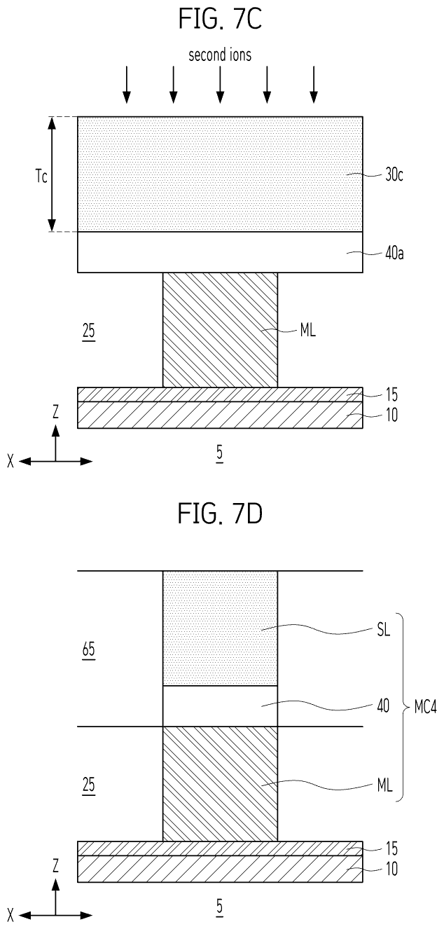

FIGS. 7A to 7D illustrate a method for forming a cell array of a semiconductor device based on an embodiment of the disclosed technology. To be specific, they are cross-sectional views taken along the line I-I′ shown in FIG. 1.

Referring to FIG. 7A, a method for forming a memory cell array of a semiconductor device based on an embodiment of the disclosed technology may include forming a lower interconnect 10, a lower interconnect barrier layer 15, a memory element layer ML, and a lower inter-layer dielectric layer 25 and forming an intermediate electrode material layer 40a and an initial selection element material layer 30a over the memory element layer ML and the lower inter-layer dielectric layer 25 by performing deposition processes, patterning processes, and planarization processes onto the base layer 5. The initial selection element material layer 30a may include a silicon oxide (SiO₂) layer, a silicon nitride (SiN) layer, or a silicon oxynitride (SiON) layer. The initial selection element material layer 30a may further include at least one of hydrogen (H) or carbon (C). The initial selection element material layer 30a may be formed to have a first thickness Ta.

Referring to FIG. 7B, the method may further include forming a first doped selection element layer 30b by performing a first doping process to diffuse first dopants into the initial selection element material layer 30a. The first doped selection element material layer 30b may have a second thickness Tb. The second thickness Tb may be greater than the first thickness Ta.

Referring to FIG. 7C, the method may further include implanting second dopants into the first doped selection element material layer 30b by performing a second doping process. The second doped selection element material layer 30c may have a third thickness Tc. In one embodiment of the disclosed technology, the third thickness Tc may be equal to the second thickness Tb. In another embodiment of the disclosed technology, the third thickness Tc may be smaller than the second thickness Tb.

Referring to FIG. 7D, the method may further include forming an intermediate electrode 40, a selection element layer SL, and an upper inter-layer dielectric layer 65 by performing patterning processes, deposition processes, and planarization processes. The selection element layer SL and the upper inter-layer dielectric layer 65 may be co-planar. A memory cell structure MC4 including the memory element layer ML, the intermediate electrode 40, and the selection element layer SL may be formed.

Subsequently, further referring to FIG. 3D, the method may further include forming an upper interconnect barrier layer 75 and an upper interconnect 70 over the memory cell structure MC4 and the upper inter-layer dielectric layer 65 by performing a deposition process and a patterning process. The upper interconnect barrier layer 75 and the upper interconnect 70 may have a shape of a conductive line extending in the second horizontal direction Y.

In some embodiments of the disclosed technology, the first doping process may include a plasma doping process, and the first dopants may include at least one of boron (B), aluminum (Al), gallium (Ga), indium (In), or thallium (Tl). The second doping process may include a plasma doping process or an ion implantation process. The second dopants may include at least one of arsenic (As), phosphorus (P), or germanium (Ge).

In an embodiment of the disclosed technology, a memory cell structure of a semiconductor device may include a selection element with reduced physical damage.

In an embodiment of the disclosed technology, since a memory cell structure of a semiconductor device may include a selection element layer including uniformly distributed dopants, a channel may be stably formed, and current leakage may be reduced.

The embodiments and implementations disclosed above are examples only, and thus various enhancements and variations to the disclosed embodiments and implementations and other embodiments and implementations can be made based on what is described and illustrated in this patent document.

What is claimed is:

1. A method for fabricating a semiconductor device, comprising:
forming a lower interconnect over a base layer;
forming a memory cell structure over the lower interconnect; and
forming an upper interconnect over the memory cell structure,
wherein the forming of the memory cell structure includes:
forming an initial selection element material layer;
performing a first doping process that provides first dopants into the initial selection element material layer to reform the initial selection element material layer into a first doped selection element material layer;
performing a second doping process that provides second dopants into the first doped selection element material layer to reform the first doped selection element material layer into a second doped selection element material layer; and
forming a selection element layer by patterning the second doped selection element material layer.

2. The method of claim 1, wherein the first dopant includes at least one of boron, aluminum, gallium, indium, or thallium.

3. The method of claim 1, wherein the second dopant includes at least one of arsenic, phosphorus, or germanium.

4. The method of claim 1, wherein the forming of the initial selection element material layer includes forming at least one of a silicon oxide layer, a silicon nitride layer, or a silicon oxynitride layer by performing a deposition process.

5. The method of claim 1, wherein the first doping process includes performing a plasma doping process.

6. The method of claim 1, wherein the second doping process includes performing one of an ion implantation process or a plasma doping process.

7. The method of claim 1, wherein the forming of the memory cell structure further includes:
forming a lower electrode material layer below the initial selection element material layer, and
forming the selection element material layer and the lower electrode by performing a patterning process.

8. The method of claim 1, wherein the forming of the memory cell structure further includes:
forming an intermediate electrode material layer over the selection element layer;
forming a memory element material layer over the intermediate electrode material layer; and
forming an intermediate electrode and a memory element layer by patterning the memory element material layer and the intermediate electrode material layer.

9. The method of claim 1, wherein the forming of the memory cell structure further includes:
forming an upper electrode material layer over the memory element material layer; and
forming a memory element layer and an upper electrode by patterning the memory element material layer and the upper electrode material layer.

10. The method of claim 1, further comprising:
forming a lower interconnect barrier layer between the lower interconnect and the memory cell structure; and
forming an upper interconnect barrier layer between the memory cell structure and the upper interconnect.

11. A method for fabricating a semiconductor device, comprising:
forming a lower interconnect;
forming a memory cell structure over the lower interconnect; and
forming an upper interconnect over the memory cell structure,
wherein the forming of the memory cell structure includes:
forming an initial selection element material layer;
reforming the initial selection element material layer into a doped selection element material layer by performing a doping process to dope first dopants and second dopants into the initial selection element material layer; and
forming a selection element layer by patterning the doped selection element material layer.

12. The method of claim 11, wherein the doping process includes performing a first plasma doping process to dope the first dopant into the initial selection element material layer.

13. The method of claim 12, wherein the doping process includes performing a second plasma doping process to dope the second dopant into the initial selection element material layer.

14. The method of claim 12, wherein the doping process includes performing an ion implantation process to dope the second dopant into the initial selection element material layer.

15. The method of claim 11, wherein the initial selection element material layer includes one of a silicon oxide layer, a silicon nitride layer, or a silicon oxynitride layer.

16. The method of claim 11, wherein the first dopant includes at least one of boron, aluminum, gallium, indium, or thallium.

17. The method of claim 11, wherein the second dopant includes at least one of arsenic, phosphorus, or germanium.

18. The method of claim 11,
wherein the doping process includes a plasma doping process using a doping gas that includes a carrier and a dopant, and
wherein the carrier includes at least one of nitrogen, oxygen, carbon, fluorine, or chlorine, and
wherein the dopant includes at least one of boron, aluminum, gallium, indium, or thallium, and at least one of arsenic, phosphorus, or germanium.
